(19) United States
(12) Patent Application Publication
(10) Pub. No.: US 2016/0372689 A1
(43) Pub. Date: Dec. 22, 2016

(54) FLEXIBLE OLED SUBSTRATE AND FLEXIBLE OLED PACKAGE METHOD

(71) Applicant: SHENZHEN CHINA STAR OPTOELECTRONICS TECHNOLOGY CO.,LTD., Shenzhen, Guangdong (CN)

(72) Inventors: Peng HAO, Shenzhen, Guangdong (CN); Changcheng LO, Shenzhen, Guangdong (CN); Xianjie LI, Shenzhen, Guangdong (CN)

(73) Assignee: Shenzhen China Star Optoelectronics Technology Co., Ltd., Shenzhen, Guangdong (CN)

(21) Appl. No.: 14/424,019

(22) PCT Filed: Feb. 8, 2015
(86) PCT No.: PCT/CN2015/072471

§ 371 Date: Feb. 25, 2015

(30) Foreign Application Priority Data
Dec. 3, 2014 (CN) 201410727845.0

(51) Int. Cl. H01L 51/00; H01L 51/52; H01L 51/56

(52) U.S. Cl. CPC H01L 51/0097; H01L 51/56; H01L 51/52

(57) ABSTRACT

The present invention provides a flexible OLED substrate and a flexible OLED package method. The flexible OLED substrate, comprising a polymer layer (1), a metal foil (2) located on the polymer layer (1) and an insulative glue layer (3) located on the metal foil (2); a surface dimension of the metal foil (2) is larger than a surface dimension of the polymer layer (1), and the surface dimension of the polymer layer (1) is larger than a surface dimension of the insulative glue layer (3). The flexible OLED substrate possesses good flexibility and waterproof, oxygen permeance proof performance. With the insulative glue layer (3), the prepared flexible element (5) is directly adhered on the substrate. The manufacture of the substrate and the package process are combined together and the package process is simplified. The stress created between the element and the substrate when the element is bent is suffered by the entire element. The reliability of the package process is promoted.

### FIELD OF THE INVENTION

The present invention relates to a display technology field, and more particularly to a flexible OLED substrate and a flexible OLED package method.

### BACKGROUND OF THE INVENTION

The flat panel display elements possess many merits of thin frame, power saving, no radiation, etc. and have been widely used. The present flat panel display elements at present mainly comprise the Liquid Crystal Display (LCD) and the Organic Light Emitting Display (OLED).

The OLED display element with the advantages of self-lighting, all solid state, high contrast, etc. has become the most potential new type display element in recent years. The biggest distinguishing feature of the OLED display element is capable of realizing the flexible display. It is an important development direction of the OLED display element to employ flexible substrate to manufacture light weight, bendable, portable flexible display element.

The traditional OLED display element utilizes hard glass substrate which can have low penetrability for oxygen and water vapor and protect the element better. The flexible substrate mainly employed for the flexible Organic Light Emitting Display element is the polymer substrate. The polymer substrate is light and thin, firm but with excellent flexibility. However, the polymer substrate itself has smaller free volume fraction and larger chain-segment average free degree. It is the destiny which can be easily penetrated by water and oxygen and shorten the lifetime of the Organic Light Emitting Display element.

When the thickness of the metal foil gets thinner below 100 μm, it shows great flexibility. In comparison with the polymer, the heat resistance is extraordinary and the thermal expansion is very low. Particularly, no water and oxygen penetration issue exist. It is so suitable as being the substrate material of the flexible Organic Light Emitting Display element. However, the conductivity and more rough surface issues still remain when the metal foil is employed as being the substrate material of the flexible display element.

As shown in FIG. 1, which shows a present polymer-metal foil composite flexible package substrate, comprising a first polymer layer 10, a metal foil 20 located on the first polymer layer 10, a second polymer layer 30 located on the metal foil 20. The surface dimension of the metal foil 20 is larger than the surface dimensions of the first polymer layer 10 and the second polymer layer 30. The conductivity and more rough surface issues can be overcome when the excellent flexibility of the metal foil and the water, oxygen resistance are utilized. However, after the manufacture of the polymer-metal foil composite flexible package substrate is accomplished, the package process is still essential for combining with the element. As shown in FIG. 2, first, the Organic Light Emitting Display element 50 is formed on the second polymer layer 30 of the flexible substrate; then, overlaying organic glue 40 on the metal foil 20 where is not covered by the first polymer layer 10 and the second polymer layer 30 and the part is adhered to the lateral side of the Organic Light Emitting Display element 50. In such kind of package structure, there is still possibility that water, oxygen still penetrate via the sealing position or the lateral side of the polymer. Meanwhile, the element is flexible, and as the element is deformed, stress may occur between the element and the substrate. The stress must be concentrated at the connection position of the package glue which the fracture can easily happen.

### SUMMARY OF THE INVENTION

An objective of the present invention is to provide a flexible OLED substrate possessing good flexibility and waterproof, oxygen permeance proof performance. With the substrate to package the OLED, the package process can be simplified and reliability of the package process can be promoted to prevent the leakage of the package sealing position from water, oxygen and the element fracture due to the concentrated stress when the flexible element is deformed.

Another objective of the present invention is to provide a flexible OLED package method. The method combines the manufacture of the substrate and the package process to simplify the package process. Meanwhile, the flexible element is directly adhered on the flexible OLED substrate. The stress created between the element and the substrate when the element is bent is suffered by the entire element. The reliability of the package process is promoted.

For realizing the aforesaid objectives, the present invention provides a flexible OLED substrate, comprising a polymer layer, a metal foil located on the polymer layer and an insulative glue layer located on the metal foil; a surface dimension of the metal foil is larger than a surface dimension of the polymer layer, and the surface dimension of the polymer layer is larger than a surface dimension of the insulative glue layer.

The metal foil is a metal foil possessing a water, oxygen isolation ability and a flexible, bendable ability.

The metal foil is an aluminum foil.

A thickness of the metal foil is between 3 μm and 100 μm.

The polymer layer is a polymer layer supporting and protecting the metal foil.

The polymer layer is a polyimide layer.

A thickness of the polymer layer is between 10 μm and 300 μm.

The present invention further provides a flexible OLED package method, comprising:

step 1, providing a metal foil, and coating and heat curing a polymer precursor solution at one side of the metal foil to form a polymer layer; step 2, uniformly overlaying an insulative glue on the other side of the metal foil with a glue coater to form an insulative glue layer, and manufacturing a flexible OLED substrate comprising the polymer layer, the metal foil and the insulative glue layer;

step 3, oppositely assembling a prepared OLED element and the flexible OLED substrate to adhere the OLED element on the flexible OLED substrate with the insulative glue layer.

The polymer precursor solution in the step 1 is a polyimide precursor solution, and the formed polymer layer is a polyimide layer, and a thickness of the polymer layer is between 10 μm and 300 μm.

An area of the insulative glue layer in the step 2 is smaller than areas of the metal foil and the polymer layer, and larger than an area of the OLED element required for package, and is located at a position covered the metal foil and the polymer layer.

The OLED element in the step 3 is a bottom emitting light type OLED element.

The present invention further provides a flexible OLED substrate, comprising a polymer layer, a metal foil located on the polymer layer and an insulative glue layer located on the metal foil; a surface dimension of the metal foil is larger than a surface dimension of the polymer layer, and the surface dimension of the polymer layer is larger than a surface dimension of the insulative glue layer;

wherein the metal foil is a metal foil possessing a water, oxygen isolation ability and a flexible, bendable ability;

wherein a thickness of the metal foil is between 3 μm and 100 μm;

wherein the polymer layer is a polymer layer supporting and protecting the metal foil;

wherein a thickness of the polymer layer is between 10 μm and 300 μm.

The benefits of the present invention are: the present invention employs an insulative glue to manufacture the flexible OLED substrate, which possesses good flexibility and waterproof, oxygen permeance proof performance. With the insulative glue layer, the prepared flexible element is directly adhered on the substrate. The manufacture of the substrate and the package process are combined together and the package process is simplified. The stress created between the element and the substrate when the element is bent is suffered by the entire element. The reliability of the package process is promoted.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flexible OLED substrate according to prior art;

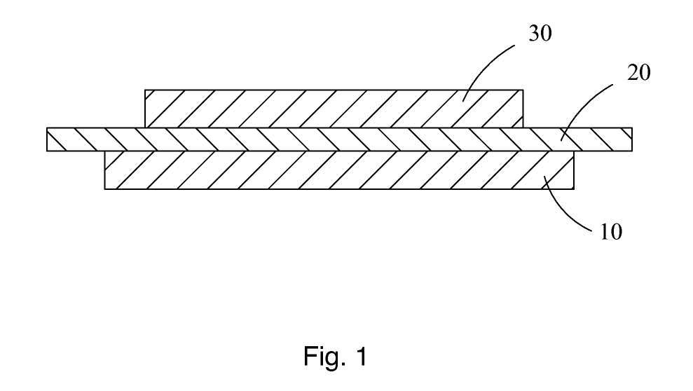

FIG. 2 is an OLED display element packaged with the flexible OLED substrate shown in FIG. 1;

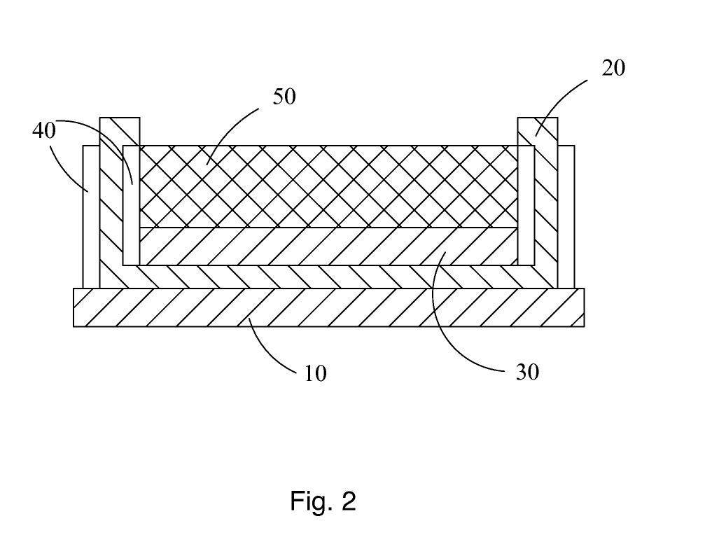

FIG. 3 is a flexible OLED substrate according to the present invention;

FIG. 4 is a flowchart of a flexible OLED package method according to the present invention;

FIG. 5 is an OLED display element packaged with the flexible OLED substrate according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

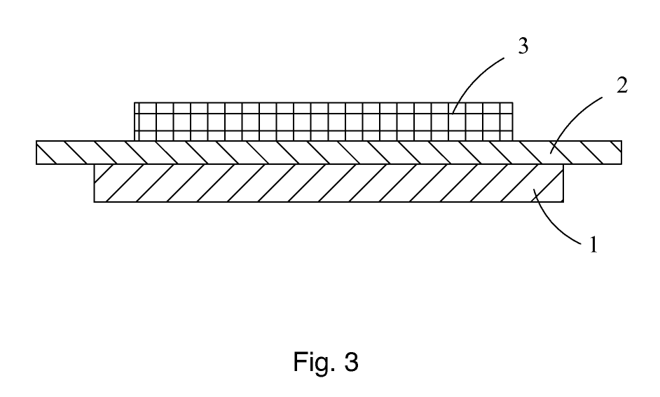

Please refer to FIG. 3. The present invention provides a flexible OLED substrate, comprising a polymer layer 1, a metal foil 2 located on the polymer layer 1 and an insulative glue layer 3 located on the metal foil 2; a surface dimension of the metal foil 2 is larger than a surface dimension of the polymer layer 1, and the surface dimension of the polymer layer 1 is larger than a surface dimension of the insulative glue layer 3.

The metal foil 2 can be any metal foil possessing a water, oxygen isolation ability and a flexible, bendable ability, and the aluminum foil can be illustrated; preferably, a thickness of the metal foil 2 is between 3 μm and 100 μm. Specifically, the polymer layer 1 can be any polymer layer supporting and protecting the metal foil 2. The polyimide layer can be illustrated; preferably, a thickness of the polymer layer is between 10 μm and 300 μm.

Specifically, the material of the insulative glue layer 3 can be insulative solid glue. The insulative glue layer 3 is in charge of adhering the OLED element on the OLED flexible substrate as packaging and possesses a certain function of isolating water, oxygen. Meanwhile, with its insulativity, the contact between the electrical metal foil and the element electrodes can be prevented.

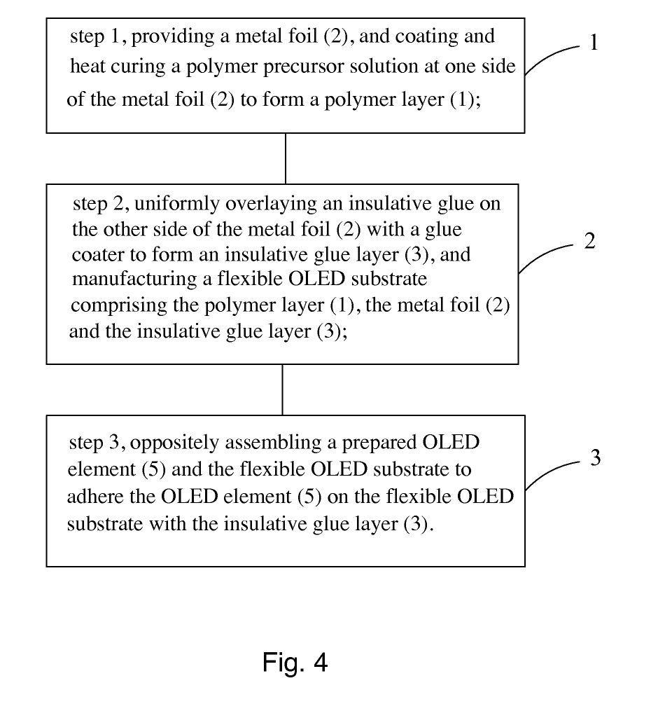

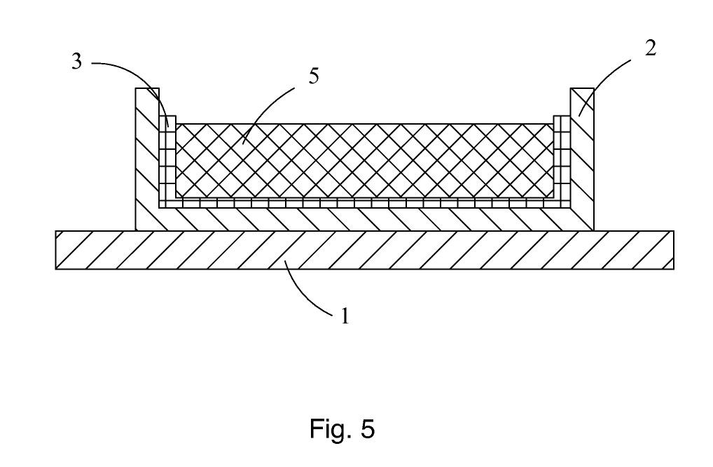

Please refer to FIG. 4, FIG. 5. The present invention further provides a flexible OLED package method, comprising:

step 1, providing a metal foil 2, and coating and heat curing a polymer precursor solution at one side of the metal foil 2 to form a polymer layer 1.

Specifically, the metal foil 2 can be an aluminum foil, and the thickness is between 3 μm and 100 μm; the polymer precursor solution can be polyimide precursor solution, and the manufactured polymer layer 1 is a polyimide layer, and the thickness is between 10 μm and 300 μm.

step 2, uniformly overlaying an insulative glue on the other side of the metal foil with a glue coater to form an insulative glue layer 3, and manufacturing a flexible OLED substrate comprising the polymer layer 1, the metal foil 2 and the insulative glue layer 3.

Significantly, the area of the metal foil 2 in the step 1 should be larger than the area of the polymer layer 1; the area of the coated insulative glue layer 3 in the step 2 should be smaller than areas of the metal foil and the polymer layer, and larger than an area of the OLED element 5 required for package, and is located at a position covered the metal foil 2 and the polymer layer 1.

step 3, oppositely assembling a prepared OLED element 5 and the flexible OLED substrate to adhere the OLED element 5 on the flexible OLED substrate with the insulative glue layer 3.

Significantly, the OLED element 5 in the step 3 is a bottom emitting light type OLED element. The insulative glue layer 3 adheres at the bottom and lateral sides of the OLED element 5. Compared with the prior arts, the OLED package method of the present invention simplifies the package process, and the insulative glue layer 3 in the manufactured package structure is an entirety but not formed by joint to prevent the leakage of the sealing position from water, oxygen. The stress created between the element and the substrate when the element is bent is suffered by the entire element. The reliability of the package process is promoted.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A flexible OLED substrate, comprising a polymer layer, a metal foil located on the polymer layer and an insulative glue layer located on the metal foil; a surface dimension of the metal foil is larger than a surface dimension of the polymer layer, and the surface dimension of the polymer layer is larger than a surface dimension of the insulative glue layer.

2. The flexible OLED substrate according to claim 1, wherein the metal foil is a metal foil possessing a water, oxygen isolation ability and a flexible, bendable ability.

3. The flexible OLED substrate according to claim 2, wherein the metal foil is an aluminum foil.

4. The flexible OLED substrate according to claim 1, wherein a thickness of the metal foil is between 3 μm and 100 μm.

5. The flexible OLED substrate according to claim 1, wherein the polymer layer is a polymer layer supporting and protecting the metal foil.

6. The flexible OLED substrate according to claim 5, wherein the polymer layer is a polyimide layer.

7. The flexible OLED substrate according to claim 1, wherein a thickness of the polymer layer is between 10 μm and 300 μm.

8. A flexible OLED package method, comprising:
step 1, providing a metal foil, and coating and heat curing a polymer precursor solution at one side of the metal foil to form a polymer layer;
step 2, uniformly overlaying an insulative glue on the other side of the metal foil with a glue coater to form an insulative glue layer, and manufacturing a flexible OLED substrate comprising the polymer layer, the metal foil and the insulative glue layer;
step 3, oppositely assembling a prepared OLED element and the flexible OLED substrate to adhere the OLED element on the flexible OLED substrate with the insulative glue layer.

9. The flexible OLED package method according to claim 8, wherein the polymer precursor solution in the step 1 is a polyimide precursor solution, and the formed polymer layer is a polyimide layer, and a thickness of the polymer layer is between 10 μm and 300 μm.

10. The flexible OLED package method according to claim 8, wherein an area of the insulative glue layer in the step 2 is smaller than areas of the metal foil and the polymer layer, and larger than an area of the OLED element required for package, and is located at a position covered the metal foil and the polymer layer.

11. The flexible OLED package method according to claim 8, wherein the OLED element in the step 3 is a bottom emitting light type OLED element.

12. A flexible OLED substrate, comprising a polymer layer, a metal foil located on the polymer layer and an insulative glue layer located on the metal foil; a surface dimension of the metal foil is larger than a surface dimension of the polymer layer, and the surface dimension of the polymer layer is larger than a surface dimension of the insulative glue layer;
wherein the metal foil is a metal foil possessing a water, oxygen isolation ability and a flexible, bendable ability;
wherein a thickness of the metal foil is between 3 μm and 100 μm;
wherein the polymer layer is a polymer layer supporting and protecting the metal foil;
wherein a thickness of the polymer layer is between 10 μm and 300 μm.

13. The flexible OLED substrate according to claim 12, wherein the metal foil is an aluminum foil.

14. The flexible OLED substrate according to claim 12, wherein the polymer layer is a polyimide layer.
